(19) United States
(12) Patent Application Publication
(10) Pub. No.: US 2022/0340031 A1
(43) Pub. Date: Oct. 27, 2022

(54) Mobile inflatable hybrid concentrating solar thermal and photovoltaic system based electric vehicle charging station

(71) Applicant: Yonghua Wang, Klamath Falls, OR (US)

(72) Inventor: Yonghua Wang, Klamath Falls, OR (US)

(21) Appl. No.: 17/300,244

(22) Filed: Apr. 26, 2021

(51) Int. Cl. B60L 53/57; H02S 10/40; H02S 10/30; H02S 40/22; H02S 40/38; H01L 35/30; H02J 7/35; B60L 53/51

(52) U.S. Cl. CPC B60L 53/57; H02S 10/40; H02S 10/30; H02S 40/22; H02S 40/38; H01L 35/30; H02J 7/35; B60L 53/51; B60L 53/35

(57) ABSTRACT

An mobile solar powered EV charging station consists of an inflatable solar concentrator based hybrid solar thermal and photovoltaic subsystem with thermoelectric activated thermal storage to store thermal storage and regenerate electric power; a battery bank subsystem to store the cogenerated electric energy from the hybrid solar thermal and photovoltaic subsystem; an electric driving subsystem to make the entire system mobile; and a control subsystem to coordinate all of the subsystem to work. The mobile EV charging station is not only able to generate electric power locally to charge EVs, but also able to transport power from solar powered EV changing station network and power grid to the sites where EVs are located.

### TECHNICAL FIELD

The present disclosure relates generally to solar powered Electric Vehicle (EV) charging stations, more specifically, to mobile inflatable concentrating photovoltaic system based EV charging station.

### BACKGROUND

Facing to the grant challenges of fossil fuel depleting and global warming, the entire world is accelerating in transiting toward the renewable energy dominated society. As one of the three major sectors of energy consumption, the world auto-industry is undergoing the transformative transition from internal combustion engine vehicles to EVs. However, the wide-spread adoption of EVs is hammered by prolonged charging time and high cost of EVs. Contrast to internal combustion engine vehicle which is based on fossil fuel with energy density 100-200 times higher than that of battery storage, EVs based on battery storage need energy replenishments frequently. Therefore EVs need the distributed charging stations, especially along highways and in remote areas, to replenish energy everywhere in time. The distribution nature of solar energy source provides the possibility to generate power anywhere locally to charge EVs in time. The power supply from solar power generation stations perfectly matches the power demand from EVs. However, due to the low energy current density of solar irradiance, solar powered EV charging stations need large areas of land to collect sufficient sunlight and generate enough power to charge EVs. Obviously, qualified solar fields for EV charging stations are not always available at where the EV charging stations are needed. Hence, mobile EV charging stations which can transfer power from fixed charging stations to EVs located in different places would be the “holy grail” to promote the wide-spread adoption of EVs. In particular, if the mobile EV charging stations are solar powered, they might be the dynamic extension of the fixed solar powered EV charging station network and serve as the interconnects between the fixed EV charging stations. Furthermore, these mobile charging stations may serve as connection between the fixed EV charging station network and the normal power grid system.

Mobile EV charging stations may function as the power transportation vehicles to transport the battery charged by fixed solar power generation stations to the sites where the EVs are located, or the solar power generation stations themselves towered or driven to the sites where they collect sunlight and generate power to charge EVs locally. US patent 2015/0288317 A1 applied by Huang et al (Huang) disclosed a solar power mobile charging station which includes a foldable solar panel and a battery configured to receive electricity generated from the solar panel and charge one or two electric vehicles. In Huang's disclosure, the solar power charging system is towered or driven to where the EVs are located, the system itself has no driving system. Huang's system is based on flat plate photovoltaic panel which has limited conversion efficiency, significant cost, and non-negligible self weight. In Huang's system, the electric power is generated locally with a foldable solar panel to charge EVs. But, the system is neither able to transport the power generated in fixed solar power generation stations located in other areas to charge EVs, nor able to transport electric power from power grid to the EV charging sites. Furthermore, Huang's system is limited by the low conversion efficiency and heavy weight of the conventional solar panels. In Huang's system, only battery is deployed to store the solar panel generated electric power, no mechanism is deployed to store the solar panel generated thermal energy and enhance electric power generation and storage.

U.S. Pat. No. 8,963,481 B2 granted to Prosser et al (Prosser) disclosed a charging service vehicle which transports battery modules to provide roadside assistance or rescue. Prosser's invention is able to transport the power generated by the solar power generation stations in other areas to the EV charging sites for charging EVs, but Prosser's vehicles can't generate power locally at the EV charging sites by using solar power.

While the combination of the prior arts can create a mobile solar power system to transport electric power and charge EVs located at different sites, it is unable to incorporate the Concentrating Photovoltaic (CPV), which has potential to significantly increase the conversion efficiency, dramatically reduce the cost, and fundamentally decrease the weight of the solar power system, into the mobile solar power system, and cogenerate electric power and thermal energy, as well as store the thermal energy and ultimately turn it back to electric power, as the present invention.

In order for the mobile solar power system to be able to charge EVs and to be charged by the fixed solar power generation stations in other areas or power grid, the mobile solar power system is equipped with an on board bi-directional charger.

The characteristics of the present invention will become more apparent as the present description proceeds.

### Objects

The objects of this invention are to: (1) create a mobile solar power system with ultra-high efficiency, substantially low cost, and super-light weight for charging EVs; (2) enable Concentrating Photovoltaic (CPV) system based mobile solar power EV changing system through adoption of the inflatable non-imaging solar conentrators; (3) make the mobile solar power system a self-drivable transportation tool to transport power between the fixed solar power stations in other areas and the EV charging sites; (4) add thermoelectric active thermal storage, addition to battery storage system, to the storage system of the mobile solar power system to store thermal energy and ultimately turn the stored thermal energy back to electric power; (5) enable the bi-directional charging of the mobile solar power system.

### SUMMARY

According to the present invention, the mobile inflatable hybrid concentrating solar thermal and photovoltaic system based electric vehicle charging station comprises: an inflatable solar concentrator based hybrid concentrating solar thermal and photovoltaic system array with thermoelectric active storage units; a battery storage system; a bi-directional charger; a control system; a self-drive system; a mobile platform.

In the system of the present invention, the components are configured in such a way that the inflatable solar concentrator combines with a photovoltaic receiver integrated with a thermoelectric active thermal storage package to form an inflatable hybrid solar thermal and photovoltaic unit with energy storage; the concentrating hybrid units are connected to form an array; the array is installed on the mobile platform to generate power to power the self-driving system of the mobile system; a battery storage system is incorporated into the mobile system to store the electric power generated from the concentrating hybrid solar thermal and photovoltaic unit array and the solar power generation systems located in other areas; a bi-directional charging system is incorporated into the mobile system to charge EVs or to be charged by solar power generation systems in other areas or power grid; a control system is incorporated into the mobile system to coordinate all the components; a self-driving system including the electric motors, power train, and electric control system is incorporated into the mobile system. When in operation, the inflatable solar concentrator concentrates both of the incident beam sunlight and diffuse sunlight to the receiver, where portion of the light is directly converted into electricity by the photovoltaic cells integrated into the hybrid solar thermal and photovoltaic receiver and the rest is converted into heat which is then extracted, raised in temperature, and stored into the thermal storage package by the thermoelectric modules integrated into the hybrid solar thermal and photovoltaic receiver; the stored thermal energy will flow through the thermoelectric modules and be turned back to electric power; the photovoltaic generated electric power is directly stored into the battery system to drive the mobile system or charge EVs; the bi-directional charger is deployed to charge EVs or get the battery system charged by the solar power system located in other areas or power grid system. Therefore, the mobile system of the present invent can either transport the power generated by the solar power systems located in other areas to the EV charging sites or generate power locally at the charging sites to charge EVs. Due to the ultra-high efficiency, substantially low cost, and super-light weight of the inflatable solar concentrator based hybrid concentrating solar thermal and photovoltaic system unit, the entire mobile system realizes ultra-high efficiency, substantially low cost, and super-light weight. Apart from battery storage, the integrated thermoelectric active thermal storage is able to store the cogenerated heat from the concentrating hybrid solar thermal and photovoltaic system, and turn it back to electric power when it is needed. The solar powered mobile system is not only able to transport power from other solar power generation stations and power grid to charging sites to charge EVs, but also able to generate power locally to charge EVs. Therefore, it has potential to turn parking lots into power generation stations.

Further aspects and advantages of the present invention will become apparent upon consideration of the following description thereof, reference being made of the following drawing.

### BRIEF DESCRIPTION OF THE DRAWINGS

The accompanying drawings, which are incorporated in and constitute a part of this specification, illustrate an embodiment of the invention and together with the description, serve to explain the principles of the invention.

FIG. 1 is the schematic indication of the mobile inflatable hybrid concentrating solar thermal and photovoltaic system based electric vehicle charging station.

FIG. 2 is the system structure of the power system embedded into the mobile inflatable hybrid concentrating solar thermal and photovoltaic system based electric vehicle charging station.

FIG. 3 is the inflatable non-imaging solar concentrator based hybrid concentrating solar thermal and photovoltaic system unit with thermoelectric activated thermal storage package.

FIG. 4 is the hybrid solar thermal and photovoltaic receiver with thermoelectric activated thermal storage package.

FIG. 5 is the cross section view of the hybrid solar thermal and photovoltaic receiver with thermoelectric activated thermal storage package

FIG. 6 is the hybrid solar thermal and photovoltaic receiver component with thermoelectric modules.

FIG. 7 is the thermal storage component of the thermoelectric activated thermal storage package.

FIG. 8 is the schematic structure of the hybrid solar thermal and photovoltaic receiver with thermoelectric activated thermal storage package and its energy storage work principle explanation.

FIG. 9 is the schematic system structure of the entire mobile inflatable hybrid concentrating solar thermal and photovoltaic system based electric vehicle charging station.

### DETAILED DESCRIPTION

Reference will now be made in detail to the present exemplary embodiments, examples of which are illustrated in the accompanying drawings. Wherever possible, the same reference numbers will be used throughout the drawings to refer to the same or like parts.

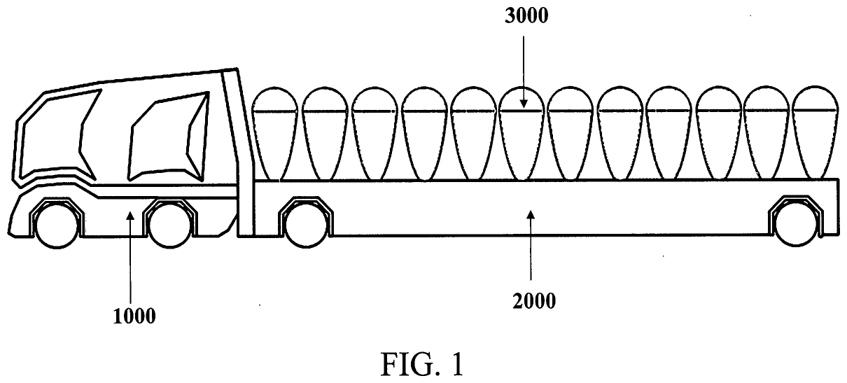

Referring to FIG. 1, the mobile inflatable hybrid concentrating solar thermal and photovoltaic system based electric vehicle charging station consists of the driving electric vehicle 1000, the mobile platform 2000, the inflatable non-imaging solar concentrator based hybrid concentrating solar thermal and photovoltaic system unit array 3000, and the bidirectional charger 4000 which is embedded into the mobile platform 2000 and is not indicated in FIG. 1.

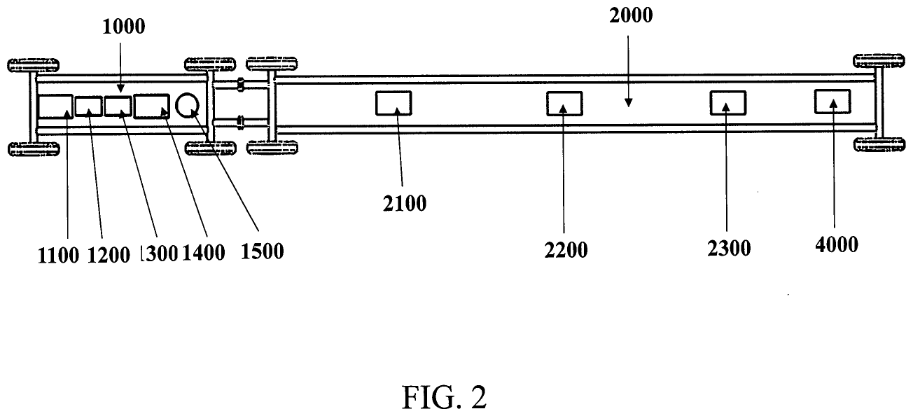

Referring to FIG. 2, the power train of the driving electric vehicle 1000 includes the battery pack 1100, the converter 1200, the inverter 1300, the Electronic Control Unit (ECU) and battery management 1400, and the electric motor 1500. The power system of the mobile charging station consists of the battery bank 2100, the control system 2200, the hybrid solar thermal and photovoltaic receiver with thermoelectric activated thermal storage 2300, and the bidirectional charger 4000.

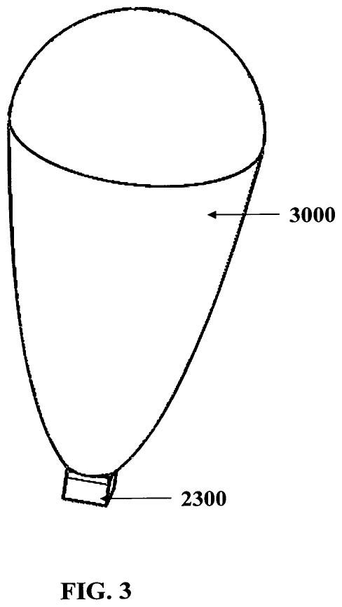

Referring to FIG. 3, when in operation, the incident sunlight concentrated by the inflatable non-imaging solar concentrators of the inflatable non-imaging solar concentrator based hybrid concentrating solar thermal and photovoltaic system unit array 3000 is coupled onto the hybrid solar thermal and photovoltaic receiver with thermoelectric activated thermal storage array 2300.

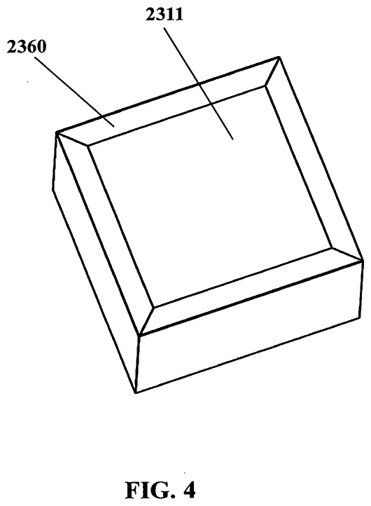

Referring to FIG. 4, the hybrid solar thermal and photovoltaic receiver with thermoelectric activated thermal storage is an insulated power generation and energy storage package.

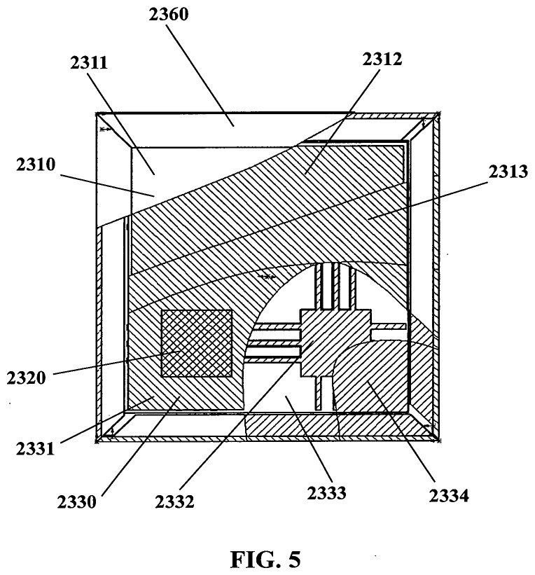

Referring to FIG. 5, the hybrid solar thermal and photovoltaic receiver with thermoelectric activated thermal storage consists of hybrid photovoltaic and thermal panel 2310 which comprises the glazing 2311, solar cell array 2312, and the metal sheet 2313, thermoelectric module 2320, thermal storage package 2330 which comprises the top insulation layer 2331, heat exchanger 2332, thermal mass 2333, and backside insulation layer 2334, and frames 2360 with side insulation materials. The hybrid photovoltaic and thermal panel 2310 is laminated and sealed; the thermoelectric modules 2320 are attached to the backside of the metal sheet 2313; the heat exchanger 2332 is attached to the thermoelectric modules surrounded by the insulation layer 2331; the heat exchanger 2332 is buried into the thermal mass which is insulated by the back side insulation layer 2334 and the side insulation materials within frames 2360. When in operation, the incident sunlight penetrates through the glazing 2311 and reaches the solar cell arrays 2312; a portion of the sunlight is converted into electricity directly, and rest become heat; the heat is extracted, boosted its temperature, and transferred to the heat exchanger 2332 by the thermoelectric modules 2320; the heat exchanger 2332 distributes the heat into the thermal mass 2333. When at night or in cloudy days, the stored heat in the thermal mass 2333 transferring through the heat exchanger 2332 and the thermoelectric modules 2320, is converted back into electricity by the thermoelectric modules 2320 which is operating in the generator mode at this movement.

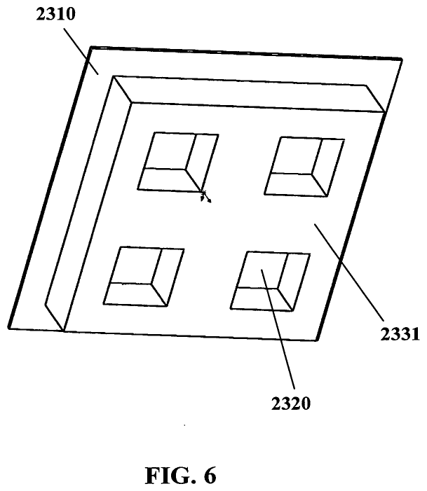

Referring to FIG. 6, the assembly of the hybrid photovoltaic and thermal panel 2310, thermoelectric modules 2320, and insulation layer 2331, is further illustrated.

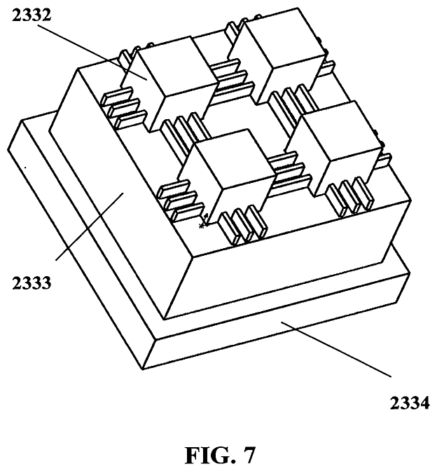

Referring to FIG. 7, the assembly of the heat exchanger 2332, thermal mass 2333 and the backside insulation layer 2334 is further illustrated.

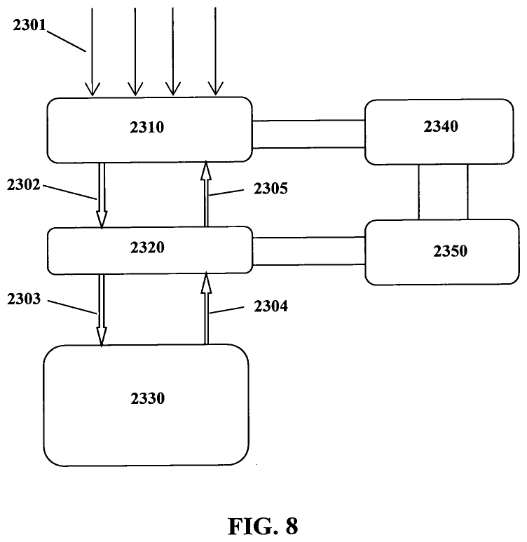

Referring to FIG. 8, the entire hybrid photovoltaic and thermal panel, thermoelectric module, and thermal storage module system comprise the hybrid photovoltaic and thermal panel 2310, thermoelectric modules 2320, thermal storage package 2330, battery bank 2340 and control system 2350. When in operation, the sunlight 2301 shines on the hybrid photovoltaic and thermal panel 2310, which cogenerates electricity and heat, the cogenerated electricity is conducted to the battery bank 2340, and the cogenerated heat 2302 is transferred to thermoelectric modules and boosted up to higher temperature heat 2303, then transferred into the thermal storage package 2330. At night or in cloudy days, the stored heat 2304 flow through the thermoelectric modules 2320 to convert it back to electricity with control system 2350 to switch the operating modes of the thermoelectric modules from cooler to generator, the heat 2305 dissipated from the thermoelectric modules 2320 is transferred back to the hybrid photovoltaic and thermal panel 2310. The thermoelectric module generated electricity is conducted to battery bank 2340 through the control system 2350.

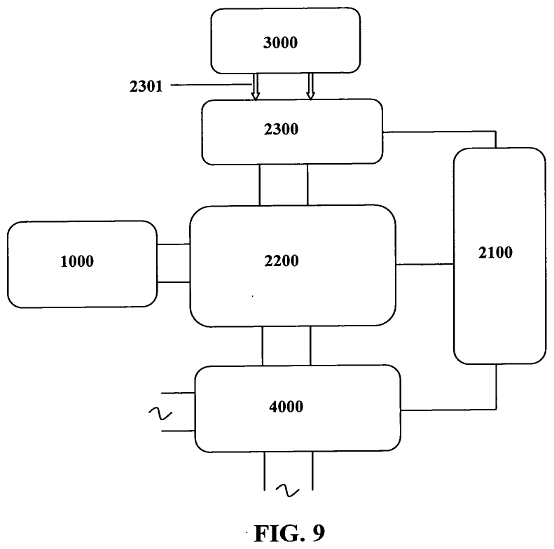

Referring to FIG. 9, the power system of the entire mobile inflatable hybrid concentrating solar thermal and photovoltaic system based electric vehicle charging station consists of the driving electric vehicle 1000, the battery bank 2200, hybrid solar thermal and photovoltaic receiver with thermoelectric activated thermal storage package array 2300, and control system 2100, which are embedded into the mobile platform, the inflatable non-imaging solar concentrator based hybrid concentrating solar thermal and photovoltaic system unit array 3000, and the bidirectional charger 4000. When in operation, the inflatable non-imaging solar concentrator array of the inflatable non-imaging solar concentrator based hybrid concentrating solar thermal and photovoltaic system unit array concentrates sunlight and couples concentrated sunlight 2301 onto the hybrid solar thermal and photovoltaic receiver with thermoelectric activated thermal storage package 2300, portion of it is converted into electricity and stored into the battery bank 2200, the rest is converted into thermal energy and raised in temperature and stored into the thermal storage. When needed, the stored thermal storage is extracted to regenerate power through the thermoelectric modules in the package. The stored power in the battery bank 2200, and the stored thermal energy in 2300 can be extracted to charge electric vehicles through the bi-directional charger 4000. The battery bank can be also charged by other solar power generation systems or power grid through the bidirectional charger 4000.

From the description above, a number of advantages of the mobile inflatable hybrid concentrating solar thermal and photovoltaic system based electric vehicle charging station become evident. The hybrid concentrating solar thermal and photovoltaic system with ultra-efficiency, extremely low cost and super light weight is used in mobile EV charging stations. The thermoelectric activated thermal storage system, which not only facilitates the energy storage, but also enhances photovoltaic power generation through cooling the photovoltaic panel, is integrated into the mobile charging station. The bidirectional charger, which can be used to charge EVs and get the mobile charging station charged by other solar generation systems and power grid to transport power from one place to another, is incorporated into the system. As a mobile system, this invention extends the solar powered EV charging station network and connect it to conventional power grid.

In the preceding specification, various preferred embodiments have been described with reference to the accompanying drawings. It will, however, be evident that various other modifications and changes may be made thereto, and additional embodiments may be implemented, without departing from the broader scope of the invention as set forth in the claims that follow. The specification and drawings are accordingly to be regarded in an illustrative rather than restrictive sense.

Other embodiments of the invention will be apparent to those skilled in the art from consideration of the specification and practice of the invention disclosed herein. It is intended that the specification and examples be considered as exemplary only, with the true scope and spirit of the invention being indicated by the following claims.

I claim:

1. A mobile inflatable hybrid concentrating solar thermal and photovoltaic system based electric vehicle charging station consists of: (a) an inflatable non-imaging solar concentrator array; (b) an electric driving system; (c) a mobile platform containing a battery bank, a hybrid solar thermal and photovoltaic receiver with thermoelectric activated storage package array; (d) a bidirectional charger; (e) a control system;
Wherein, the inflatable non-imaging solar concentrator array is optically coupled to the hybrid solar thermal and photovoltaic receiver with thermoelectric activated storage package array of the mobile platform; the hybrid solar thermal and photovoltaic receiver with thermoelectric activated storage package array is connected to the battery bank with electric cables; the bidirectional charger is connected with the battery bank with electric cables; and the control system is connected to the battery bank, hybrid solar thermal and photovoltaic receiver with thermoelectric activated storage package array, and the bidirectional charger with electric cables; the electric driving system is connected with the mobile platform, and the inflatable non-imaging solar concentrator array, the hybrid solar thermal and photovoltaic receiver with thermoelectric activated storage package array, the bidirectional charger, the battery bank, the control system, are mounted on the mobile platform;
When in operation, the inflatable non-imaging solar concentrator based concentrating hybrid solar thermal and photovoltaic system with thermoelectric activated storage package array cogenerate electric power and thermal energy, the cogenerated electric power is used to charge the battery bank, and the cogenerated heat is stored in the thermal storage to be extracted out and turned back to electric power to charge the battery bank at night or in cloudy days; the battery bank is used to charge EVs through the bidirectional charger; in the case when the cogenerated power is not enough to charge multiple EVs, the battery bank of the charging station can be charged by other solar power generation stations or conventional power grid through the bidirectional charger, then transport power to the EVs located in other sites.

2. The electric driving system of claim 1 consists of a battery bank, a converter, an inverter, a motor, an Electronic Control Unit (ECU) and battery management system.

3. The hybrid solar thermal and photovoltaic receiver with thermoelectric activated thermal storage package of claim 1, consists of a hybrid photovoltaic and thermal panel, which comprises a glazing, a solar cell array, and a metal sheet, thermoelectric modules, thermal storage package, which comprises a top insulation layer, a heat exchanger, thermal mass, and a backside insulation layer, and frames with side insulation materials.

4. The hybrid photovoltaic and thermal panel of claim 3, is laminated and sealed.

5. The thermoelectric modules of claim 3, are attached to the backside of the metal sheet and the heat exchanger is attached to the thermoelectric modules surrounded by the insulation layer.

6. The heat exchanger of claim 3, is buried into the thermal mass which is insulated by the back side insulation layer and the side insulation materials within frames
When in operation, the incident sunlight penetrates through the glazing and reaches the solar cell arrays; a portion of the sunlight is converted into electricity directly, and rest become heat; the heat is extracted, boosted its temperature, and transferred to the heat exchanger by the thermoelectric modules; the heat exchanger distributes the heat into the thermal mass; When at night or in cloudy days, the stored heat in the thermal mass transferring through the heat exchanger and the thermoelectric modules, is converted back into electricity by the thermoelectric modules which is operating in the generator mode at this movement.
